(19) United States
(12) Patent Application Publication
(10) Pub. No.: US 2014/0184048 A1
(43) Pub. Date: Jul. 3, 2014

(54) MOBILE DEVICE PROTECTIVE JACKET HAVING AN ANTI-LOOSE STRUCTURE

(71) Applicant: Wen Chen Hsiung, Minxiong Township (TW)

(72) Inventor: Wen Chen Hsiung, Minxiong Township (TW)

(21) Appl. No.: 13/732,776

(22) Filed: Jan. 2, 2013

(51) Int. Cl. H05K 5/03

(52) U.S. Cl. CPC H05K 5/03
USPC 312/334.1

(57) ABSTRACT

A mobile device protective jacket includes a frame, a slidable shutter mounted on the frame to function as a slidable component and a pair of anti-loose blocks also mounted on the frame to function as a slidable component, and, after a mobile device is in its entirety confined to the mobile device protective jacket, the slidable shutter is capable of use in preventing the mobile device having a touch panel from being scratched or scraped and the pair of anti-loose blocks are capable of use in preventing the mobile device from being loosen or escaped from the mobile device protective jacket.

### BACKGROUND OF THE INVENTION

1. Field of the Invention

The present invention relates to a mobile device protective jacket, and more particularly, to a mobile device protective jacket having an anti-loose means for preventing mobile device from being escaped from the mobile device protective jacket thereof.

2. Description of the Related Art

FIG. 1 shows a given mobile device protective jacket 10 served a purpose of preventing a touch panel 51 of a mobile device 50 from being scratched or scraped, which comprises a frame 20 and a slidable shutter 30 made of flexible material and also mounted on the frame 20 to function as a slidable component of the frame 20.

The frame 20 is molded as a unitary structure which comprises two U-shaped blocks 21a and 21b, a first connection panel 25 and a second connection panel 26 disposed beneath the first connection panel 25, wherein each U-shaped block 21a or 21b has an accommodation chamber E2 thereof, and both the first connection panel 25 and the second connection panel 26 together separate said U-shaped blocks 21a and 21b by a distance.

Hence, an insertion chamber E1 located between the first connection panel 25 and the second connection panel 26 of the frame 20 is then formed to communicate with each accommodation chamber E2 of the U-shaped blocks 21a or 21b thereof. And, a window-shaped chamber E3 located between said spaced-apart U-shaped blocks 21a and 21b of the frame 20 is also defined to communicate with both the insertion chamber E1 and the accommodation chambers E2.

Accordingly, the insertion chamber E1, the accommodation chambers E2 and the window-shaped chamber E3 of the mobile device protective jacket 10 are together established an assembly space for the mobile device 50 capably assembled within or detached from the space thereof.

To mount the slidable shutter 30 on the frame 20, a U-shaped groove 28 is disposed on one side near the window-shaped chamber E3 of each said spaced-apart U-shaped block 21a and 21b. Each U-shaped groove 28 not only respectively holds one end of the slidable shutter 30, but also enables the mounted slidable shutter 30 to function as a slidable component capable of sliding along the U-shaped grooves 28. Therefore, the window-shaped chamber E3 of the mobile device protective jacket 10 can be opened or shut by sliding movement of the slidable shutter 30.

When in use, the mobile device 50 after completely inserted into the insertion chamber E1 of the mobile device protective jacket 10 shall be in its entirety confined to the mobile device protective jacket 10. At this point in time, the touch panel 51 of the mobile device 50 is placed under the protection of the slidable shutter 30 of the mobile device protective jacket 10 such that, even if the mobile device protective jacket 10 is hit, the slidable shutter 30 can still prevent the touch panel 51 of the mobile device 50 from being scratched or scraped.

But, since the mobile device protective jacket 10 still has not designed an anti-loose means for preventing mobile device from detachment from the mobile device protective jacket 10 thereof, there is a still drawback that the mobile device 50 if assembled within the mobile device protective jacket 10 inevitably may be loosen from the mobile device protective jacket 10.

### SUMMARY OF THE INVENTION

In view of this, it is a primary objective of the present invention to provide a mobile device protective jacket having an anti-loose structure includes a frame, a slidable shutter mounted on the frame to function as a slidable component and a pair of anti-loose blocks also mounted on the frame to function as a slidable component, and has unexpected effects including after a mobile device is in its entirety confined to the mobile device protective jacket the slidable shutter is capable of use in preventing the mobile device having a touch panel from being scratched or scraped and the pair of anti-loose blocks are capable of use in preventing the mobile device from being loosen or escaped from the mobile device protective jacket.

It is a further objective of the present invention to provide a mobile device protective jacket having an anti-loose structure constructed as the Claims described to prevent the mobile device from being loosen or escaped from the mobile device protective jacket.

### BRIEF DESCRIPTION OF THE DRAWINGS

FIG. 1 is a schematic view of a given mobile device protective jacket served a purpose of preventing a mobile device from being scratched or scraped;

FIG. 2 is a schematic outline view of a mobile device protective jacket of the present invention;

FIG. 3 is a partially exploded view of the mobile device protective jacket of the present invention of FIG. 2; and

FIG. 4 is a schematic view of the mobile device protective jacket of FIG. 2 for use with a mobile device, showing that the mobile device protective jacket uses anti-loose blocks to prevent the mobile device from being loosen or escaped from the mobile device protective jacket according to the present invention.

### DETAILED DESCRIPTION OF THE INVENTION

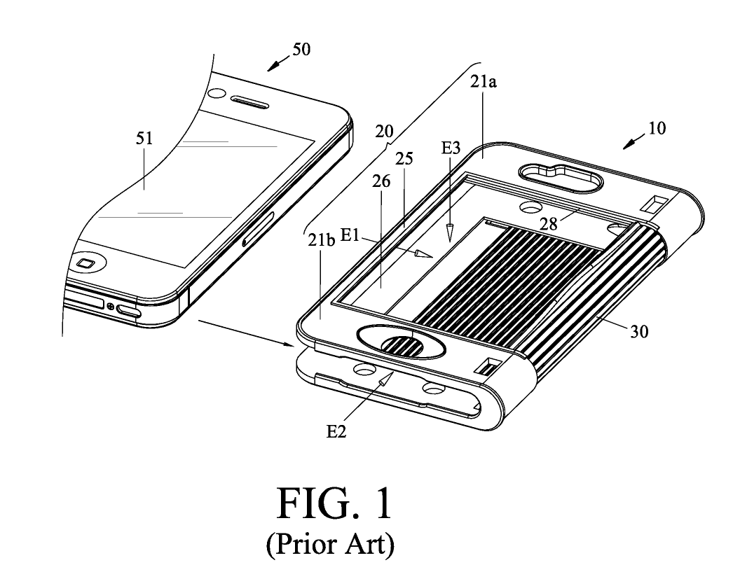

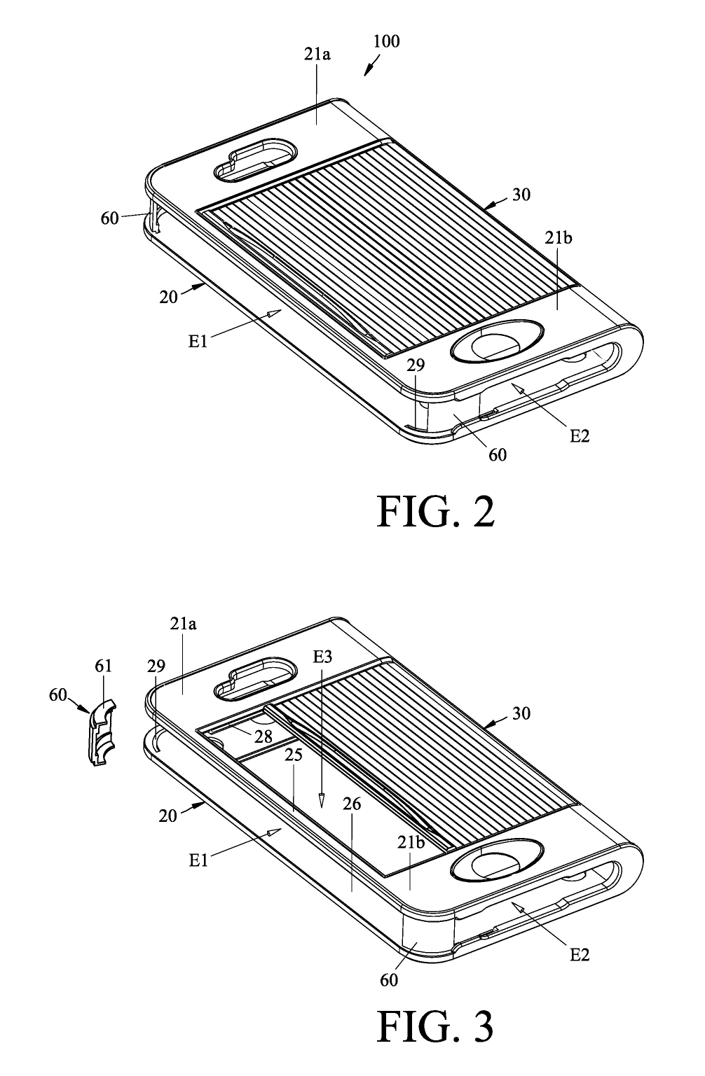

As shown in FIG. 2 and FIG. 3, a mobile device protective jacket 100 of the present invention is based on the main structure of the given mobile device protective jacket 10 of FIG. 1, which comprises a frame 20, a slidable shutter 30 and a pair of anti-loose blocks 60 having the same identical structure, wherein the slidable shutter 30 made of flexible material and mounted on the frame 20 to function as a slidable component of the frame 20, and the anti-loose block 30 made of flexible material and also mounted on the frame 20 to function as a slidable component of the frame 20.

The frame 20 comprises two U-shaped blocks 21a and 21b separated by a distance and each having an accommodation chamber E2 thereof, a first connection panel 25 having one end connected with the U-shaped blocks 21a and the other end connected with the U-shaped blocks 21b, and a second connection panel 26 disposed beneath the first connection panel 25 and also having one end connected with the U-shaped blocks 21a and the other end connected with the U-shaped blocks 21b, wherein an insertion chamber E1 located between the first connection panel 25 and the second connection panel 26 of the frame 20 is formed to communicate with each accommodation chamber E2 of the U-shaped blocks 21a or 21b thereof. And, a window-shaped chamber E3 located between said spaced-apart U-shaped blocks 21a and 21b of the frame 20 is also defined to communicate with both the insertion chamber E1 and the accommodation chambers E2.

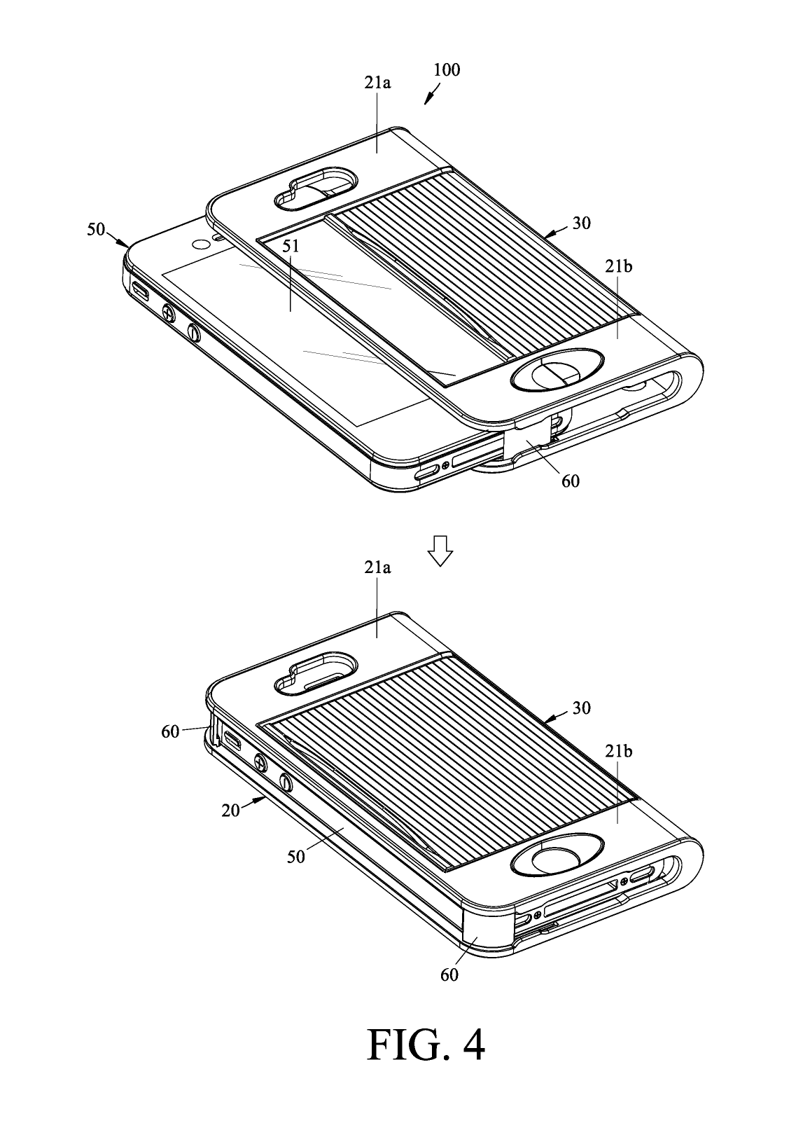

As shown in FIG. 3 and FIG. 4, the insertion chamber E1, the accommodation chambers E2 and the window-shaped chamber E3 of the mobile device protective jacket 100 of the present invention are together established an assembly space for a mobile device 50 having a touch panel 51 capably assembled within or detached from the space thereof.

As shown in FIG. 3, to mount the slidable shutter 30 on the frame 20, a U-shaped groove 28 is disposed on each face-to-face side of said spaced-apart U-shaped blocks 21a and 21b. Each U-shaped groove 28 not only respectively holds one end of the slidable shutter 30, but also enables the mounted slidable shutter 30 to function as a slidable component capable of sliding along the U-shaped grooves 28. Therefore, the window-shaped chamber E3 of the mobile device protective jacket 100 of the present invention can be opened or shut by sliding movement of the slidable shutter 30.

As shown in FIG. 2 and FIG. 3, each anti-loose block 60 has two tongue-shaped plates 61 extended from both top side and bottom side respectively for use in mounting to the frame 20.

To mount the anti-loose blocks 60 capable of sliding movement on the frame 20, near each border between the insertion chamber E1 and the accommodation chambers E2 of the frame 20 has a pair of face to face curved grooves 29 disposed thereof, i.e., each U-shaped block 21a or 21b of the frame 20 respectively has a pair of curved grooves 29 disposed in such manner that one curved groove 29 is disposed on one of U-shaped sides of the U-shaped block 21 and the other curved groove 29 is face to face disposed on the other U-shaped sides of the U-shaped block 21.

Accordingly, when each tongue-shaped plate 61 of the anti-loose blocks 60 is respectively inserted into the corresponding face to face curved grooves 29 of each U-shaped block 21a or 21b of the frame 20, one anti-loose block 60 is capable of being mounted on each U-shaped block 21a or 21b of the frame 20 to function as a slidable component as well as capable of sliding movement on the frame 20 in such manner of freely being moved forward or backward along the curved grooves 29 respectively.

Therefore, as shown in FIG. 2 and FIG. 3, the width of the insertion chamber E1 of the frame 20 can be changed and regulated by sliding movement of the anti-loose blocks 60 if moved along the curved grooves 29 in forward direction to narrow the width or if moved in backward direction to enlarge the width.

As shown in FIG. 4, when in use, each anti-loose block 60 of the frame 20 is moved backward to a rear limit position of the curved groove 29 so that the mobile device 50 is then capable of being completely inserted into and assembled within the insertion chamber E1 of the mobile device protective jacket 100 of the present invention. And, after the mobile device 50 is in its entirety confined to the mobile device protective jacket 100 of the present invention, each anti-loose block 60 of the frame 20 is moved forward to a front limit position of the curved groove 29. At this time, both sides of the insertion chamber E1 of the frame 20 are blocked with the anti-loose blocks 60, and the width of the insertion chamber E1 is narrowed enough to prevent the mobile device 50 from being loosen or escaped from the mobile device protective jacket 100 of the present invention.

At the same time, the touch panel 51 of the mobile device 50 is placed under the protection of the slidable shutter 30 of the mobile device protective jacket 100 of the present invention such that, even if the mobile device protective jacket 100 is hit, the slidable shutter 30 can still prevent the touch panel 51 of the mobile device 50 from being scratched or scraped.

When the mobile device 50 needs to be detached from the mobile device protective jacket 100 of the present invention, each anti-loose block 60 is repeatedly moved backward to the rear limit position of the curved groove 29 of the frame 20 to enlarge and restore the width of the insertion chamber E1 of the frame 20 again, and then the mobile device 50 is easily capable of being detached from the mobile device protective jacket 100 of the present invention.

What is claimed is:

1. A mobile device protective jacket comprising a frame, a slidable shutter made of flexible material and mounted on the frame to function as a slidable component, and a pair of anti-loose blocks having the same identical structure and also mounted on the frame to function as a slidable component, wherein
the frame constructed as a unitary structure comprises two U-shaped blocks separated by a distance and each having an accommodation chamber (E2) thereof, a first connection panel having one end connected with one of the U-shaped blocks and the other end connected with the other U-shaped block, and a second connection panel disposed beneath the first connection panel and having one end connected with one of the U-shaped blocks and the other end connected with the other U-shaped block; wherein an insertion chamber (E1) located between the first connection panel and the second connection panel is formed to communicate with each accommodation chamber (E2) of the U-shaped blocks thereof, a window-shaped chamber (E3) located between the spaced-apart U-shaped blocks is defined to communicate with both the insertion chamber (E1) and the accommodation chambers (E2), and each U-shaped block has a U-shaped groove disposed on one side near the window-shaped chamber (E3) thereof and a pair of face to face curved grooves disposed to near each border between the insertion chamber (E1) and the accommodation chambers (E2) of the U-shaped block thereof;
the slidable shutter has two ends slidably mounted into each corresponding U-shaped grooves of the frame respectively to enable the slidable shutter by sliding to open or shut the window-shaped chamber (E3) of the frame; and
each anti-loose block has two tongue-shaped plates extended from both top side and bottom side and slidably mounted into each corresponding face to face curved grooves of the U-shaped block respectively to enable the anti-loose blocks by sliding to narrow or restore the width of the insertion chamber (E1) of the frame.
